(19) United States
(12) Patent Application Publication
(10) Pub. No.: US 2026/0211072 A1
(43) Pub. Date: Jul. 23, 2026

(54) MAGNETIC RESONANCE IMAGING SYSTEM AND EDDY CURRENT ACQUISITION METHOD THEREFOR

(71) Applicant: GE Precision Healthcare LLC, Waukesha, WI (US)

(72) Inventors: Qilin Lu, Beijing (CN); Shuxia Wang, Beijing (CN); Ye Li, Beijing (CN); Zhikang Tian, Beijing (CN)

(21) Appl. No.: 19/451,476

(22) Filed: Jan. 16, 2026

(30) Foreign Application Priority Data
Jan. 17, 2025 (CN) 202510084330.1

(51) Int. Cl. G01R 33/565; G01R 33/58

(52) U.S. Cl. CPC G01R 33/56518; G01R 33/58

(57) ABSTRACT

A magnetic resonance imaging system and an eddy current acquisition method therefor are provided. The method includes: scanning a phantom by using a scan sequence within the N^{th} repetition time, the scan sequence including at least a first gradient pulse for generating an eddy current, and N being an integer greater than or equal to 2; acquiring a magnetic resonance signal from the phantom in at least one signal acquisition segment within the N^{th} repetition time; wherein a start time T_{N} of the M^{th} signal acquisition segment within the N^{th} repetition time is equal to a start time T_{N-1} of the M^{th} signal acquisition segment within the (N−1)^{th} repetition time plus a first preset value T; and determining an eddy current characteristic according to the acquired magnetic resonance signal.

### CROSS REFERENCE TO RELATED APPLICATIONS

The present application claims priority and benefit of Chinese Patent Application No. CN 202510084330.1 filed on Jan. 17, 2025, which is incorporated herein by reference in its entirety.

### TECHNICAL FIELD

Embodiments of the present application relate to the technical field of medical devices, and in particular, to a magnetic resonance imaging system and an eddy current acquisition method therefor.

### BACKGROUND

Magnetic resonance imaging systems have been widely used in the medical diagnostic field. The basic principle of the magnetic resonance imaging systems includes that a magnet is used to generate a uniform strong magnetic field, hydrogen atoms in the body of a subject to be diagnosed are polarized under the coordination of a specific gradient field generated by a gradient coil, and then a radio frequency coil emits a radio frequency pulse to excite hydrogen atomic nuclei, to cause nuclear resonance and absorb energy. After the radio frequency pulse is stopped, the hydrogen nuclei emit a radio signal at a specific frequency, and release the absorbed energy, which is to be received by an external receiver and processed by an electronic computer to obtain an image.

Therefore, in a magnetic resonance imaging process, the gradient magnetic field, together with the main magnetic field and the radio frequency magnetic field, constitutes three major elements of magnetic resonance imaging. The gradient magnetic field is generated by a gradient coil, and a current in the gradient coil is rapidly switched over time, so that eddy currents may be generated in surrounding conductor structures. The eddy currents may generate a secondary magnetic field superimposed with the original gradient magnetic field, resulting in imaging artifacts and image distortion. To effectively compensate for these impacts, a model of the eddy current field may be established. Typically, the eddy current field is decomposed into components of different orders in the model. A first-order eddy current refers to an eddy current component of the eddy current field that linearly changes in space. Such a linear component may cause an overall enlargement or reduction of the gradient magnetic field, affecting scaling of an image and causing scale distortion. A high-order eddy current refers to an eddy current component that exhibits a non-linear change in space, including a second-order, a third-order, and a higher-order component. The high-order components may cause more complex spatial distortion, for example, non-linear distortion such as bending and twisting of an image.

### SUMMARY OF THE INVENTION

In an existing eddy current measurement method, magnetic resonance signals may be acquired at a plurality of echoes by using a gradient echo sequence, and space-time distribution of the eddy current is deduced from the acquired signals. However, the inventors have found that due to the restriction of the minimum echo time (TE) of the magnetic resonance system, according to the existing method, only limited sampling points can be acquired within a short period of time after an eddy current is generated, and therefore the method is suitable for measuring an eddy current having a relatively long time constant, but it is difficult to capture a high-order eddy current change having a short time constant. Therefore, measurement accuracy of a high-order eddy current having a short time constant is insufficient.

In view of at least one of the above problems, embodiments of the present application provide a magnetic resonance imaging system and an eddy current acquisition method therefor.

According to an aspect of the embodiments of the present application, an eddy current acquisition method for a magnetic resonance imaging system is provided. The method comprises: scanning a phantom by using a scan sequence within the N^{th} repetition time, the scan sequence comprising at least a first gradient pulse for generating an eddy current, and N being an integer greater than or equal to 2. The method also includes acquiring a magnetic resonance signal from the phantom in at least one signal acquisition segment within the N^{th} repetition time; wherein a start time T_{N} of the M^{th} signal acquisition segment within the N^{th} repetition time is equal to a start time T_{N-1} of the M^{th} signal acquisition segment within the (N−1)^{th} repetition time plus a first preset value T, and M is an integer greater than or equal to 1; and determining an eddy current characteristic according to the acquired magnetic resonance signal.

According to an aspect of the embodiments of the present application, a magnetic resonance imaging system is provided, the system includes a scanning unit; and a controller, which is configured to execute the eddy current acquisition method described in the previous aspect.

One of the beneficial effects of the embodiments of the present application is that: By means of cyclic delayed acquisition, time locations of signal acquisition within different TRs are changed, so that a sufficient number of sampling points are obtained within a short time after the eddy current is generated to fit an eddy current curve, thereby accurately acquiring high-order eddy current changes having short time constants.

With reference to the following description and drawings, specific implementations of the embodiments of the present application are disclosed in detail, and the way in which the principles of the embodiments of the present application can be employed are illustrated. It should be understood that the implementations of the present application are not limited in scope thereby. Within the scope of the spirit and clauses of the appended claims, the implementations of the present application comprise many changes, modifications, and equivalents.

### BRIEF DESCRIPTION OF THE DRAWINGS

The included drawings are used to provide further understanding of the embodiments of the present application, which constitute a part of the description and are used to illustrate the implementations of the present application and explain the principles of the present application together with textual description. Evidently, the drawings in the following description are merely some embodiments of the present application, and those of ordinary skill in the art may obtain other implementations according to the drawings without involving inventive effort. In the drawings:

FIG. 1 is a schematic diagram of a magnetic resonance imaging system according to embodiments of the present application;

FIG. 2 is a schematic diagram of an eddy current acquisition method according to embodiments of the present application;

FIG. 3 is a schematic diagram of a scan sequence according to embodiments of the present application;

FIG. 4 is a schematic diagram of an implementation of operation 203 according to embodiments of the present application;

FIG. 5 is a schematic diagram of an eddy current acquisition method according to embodiments of the present application;

FIG. 6 is a schematic diagram of an eddy-current curve according to embodiments of the present application;

FIG. 7 is a schematic diagram of an eddy current acquisition method according to embodiments of the present application; and

FIG. 8 is a schematic diagram of an eddy current acquisition method according to embodiments of the present application.

### DETAILED DESCRIPTION

The aforementioned and other features of the embodiments of the present application will become apparent from the following description with reference to the drawings. In the description and drawings, specific implementations of the present application are disclosed in detail, and part of the implementations in which the principles of the embodiments of the present application may be employed are indicated. It should be understood that the present application is not limited to the described implementations. On the contrary, the embodiments of the present application include all modifications, variations, and equivalents which fall within the scope of the appended claims.

In the embodiments of the present application, the terms “first”, “second”, etc. are used to distinguish different elements from one another by title, but do not represent the spatial arrangement, temporal order, etc. of the elements, and the elements should not be limited by said terms. The term “and/or” includes any one of and all combinations of one or more associated listed terms. The terms “comprise”, “include”, “have”, etc., refer to the presence of stated features, elements, components, or assemblies, but do not exclude the presence or addition of one or more other features, elements, components, or assemblies.

In the embodiments of the present application, the singular forms “a”, “the”, etc. include plural forms, and should be broadly construed as “a type of” or “a class of” rather than being limited to the meaning of “one”. Furthermore, the term “the” should be construed as including both the singular and plural forms, unless otherwise explicitly specified in the context. In addition, the term “according to” should be construed as “at least in part according to . . . ”, and the term “based on” should be construed as “at least in part based on . . . ”, unless otherwise explicitly specified in the context.

The features described and/or illustrated for one embodiment may be used in one or more other embodiments in an identical or similar manner, combined with features in other embodiments, or replace features in other embodiments. The term “include/comprise” when used herein refers to the presence of features, integrated components, steps, or assemblies, but does not exclude the presence or addition of one or more other features, integrated components, steps, or assemblies.

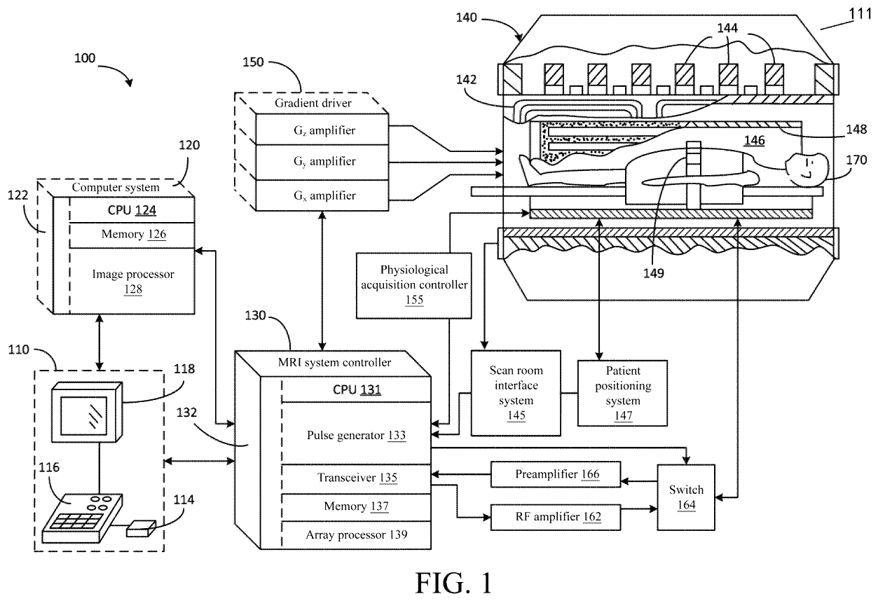

For ease of understanding, FIG. 1 shows a magnetic resonance imaging (MRI) system 100 according to some embodiments of the present invention.

The MRI system 100 includes a scanning unit 111. The scanning unit 111 is used to perform a magnetic resonance scan on a subject (for example, a human body) 170 to generate image data of a region of interest of the subject 170. The region of interest may be a predetermined anatomical site or anatomical tissue.

Operation of the MRI system 100 is controlled by an operator workstation 110, and the operator workstation 110 includes an input device 114, a control panel 116, and a display 118. The input device 114 may be a joystick, a keyboard, a mouse, a trackball, a touch-activated screen, voice control, or any similar or equivalent input device. The control panel 116 may include a keyboard, a touch-activated screen, voice control, a button, a slider, or any similar or equivalent control device. The operator workstation 110 is coupled to and communicates with a computer system 120, and the computer system enables an operator to control the generation and viewing of an image on the display 118. The computer system 120 includes a plurality of components that communicate with one another by means of an electrical and/or data connection module 122. The connection module 122 may employ a direct wired connection, a fiber optic connection, a wireless communication link, etc. The computer system 120 may include a central processing unit (CPU) 124, a memory 126, and an image processor 128. In some embodiments, the image processor 128 may be replaced with an image processing function implemented in the CPU 124. The computer system 120 may be connected to an archival media device, a persistent or backup memory, or a network. The computer system 120 may be coupled to and communicate with a separate MRI system controller 130.

The MRI system controller 130 includes a set of components that communicate with one another by means of an electrical and/or data connection module 132. The connection module 132 may employ a direct wired connection, a fiber optic connection, a wireless communication link, etc. The MRI system controller 130 may include a CPU 131, a sequential pulse generator 133 that communicates with the operator workstation 110, a transceiver (or an RF transceiver) 135, a memory 137, and an array processor 139. In some embodiments, the sequential pulse generator 133 may be integrated into the scanning unit 111 of the MRI system 100. The MRI system controller 130 may receive a command from the operator workstation 110 and is coupled to the scanning unit 111, to indicate a scan sequence that is to be executed during an MRI scan, so as to control the scanning unit 111 to execute the above-described magnetic resonance scan procedure. The “scan sequence” above refers to a combination of pulses that have specific intensities, shapes, timings, and the like applied during the execution of a magnetic resonance scan. The pulses may typically include, for example, a radio frequency pulse and a gradient pulse. The radio frequency pulses may include radio frequency excitation pulses for exciting a human body tissue, and may further include radio frequency refocusing pulses, inverse recovery pulses, etc.. Typically, a plurality of scan sequences may be preset in the magnetic resonance system, so that a sequence suitable for clinical examination requirements can be selected. The clinical examination requirements may include, for example, an imaging site, an imaging function, an imaging effect, and the like.

The scanning unit 111 may include a superconducting magnet having a superconducting coil 144, a radio frequency coil assembly, and a gradient coil assembly 142. During operation, the superconducting coil 144 provides a static uniform longitudinal magnetic field B₀ throughout the cylindrical imaging volume 146. The radio frequency coil assembly may include a radio frequency transmit coil and a radio frequency receive coil. The radio frequency transmit coil includes, for example, a body coil 148 or a local coil. The radio frequency receive coil includes, for example, a body coil 148 or a surface coil 149. A subject 170 to undergo a magnetic resonance scan may be positioned within the cylindrical imaging volume 146 of the scanning unit 111.

The MRI system controller 130 provides gradient waveforms to a gradient driver system 150, and the gradient driver system includes Gₓ (x direction), G_{y} (y direction), and G_{z} (z direction) amplifiers, etc. Each of the Gₓ, G_{y}, and G_{z} gradient amplifiers excites a corresponding gradient coil in the gradient coil assembly 142, to generate a magnetic field gradient used to spatially encode an MR signal during an MRI scan.

The x direction may also be referred to as a frequency encoding direction or a kₓ direction in k-space. The y direction may be referred to as a phase encoding direction or a k_{y} direction in the k-space. Gₓ may be used for frequency encoding or signal readout, and is generally referred to as a frequency encoding gradient or a readout gradient. G_{y} may be used for phase encoding, and is generally referred to as a phase encoding gradient. G_{z} may be used for slice (layer) position selection to obtain k-space data. It should be noted that a layer selection direction, a phase encoding direction, and a frequency encoding direction may be modified according to actual requirements.

In a transmit mode, a radio frequency excitation pulse sent by the pulse generator 133 may be generated by a transmit portion of the transceiver 135 (for example, including the radio frequency signal generator), and the radio frequency excitation pulse is amplified by a radio frequency power amplifier 162. Specifically, the radio frequency signal generator may generate the corresponding radio frequency excitation pulse based on the description (for example, including one or more of the amplitude, frequency, transmit power, etc.) of the radio frequency pulse in the predetermined scan sequence. The amplified radio frequency excitation pulse is provided to the radio frequency transmit coil by means of a transmit/receive switch (T/R switch) 164, and the radio frequency transmit coil in turn provides a radio frequency field B₁. The radio frequency field B₁ is substantially perpendicular to B₀ throughout the entire cylindrical imaging volume 146. The radio frequency field B₁ is used to excite stimulated nuclei in the body of the subject 170 so as to generate an MR signal. The T/R switch 164 may be controlled by a signal from the sequential pulse generator 133 to couple, when in the transmit mode, the RF amplifier 162 to the radio frequency transmit coil and decouple, when in a receive mode, the radio frequency transmit coil from the RF amplifier 162.

In the receive mode, the MR signals emitted by excited nuclei in the body of the subject 170 may be sensed and received by an RF body coil 148 or other radio frequency receive coils and then amplified by means of a preamplifier 166.

In some embodiments, amplified MR signals are demodulated, filtered, and digitized in a receive portion of the transceiver 135.

As a non-limiting example, a transmit portion in the transceiver 135, the radio frequency power amplifier 162, and the like constitute at least a portion of a radio frequency transmit link. Furthermore, the receive portion in the transceiver 135, the preamplifier 166, the radio frequency signal demodulator (not shown), and the like constitute at least a portion of a radio frequency receive link. One or a plurality of modules/elements/assemblies of the radio frequency transmit link and the radio frequency receive link are integrated in the scanning unit 111.

The MR signals described above may be stored as raw data in the memory 137 in the MRI system controller 130, and a reconstructed magnetic resonance image may be acquired by transforming/processing the stored raw data. For example, for each image that is to be reconstructed, the data is rearranged into separate k-space data arrays, and each of the separate k-space data arrays is input into the array processor 139. The array processor 139 is operated to transform the data into an array of image data by means of a Fourier transform.

The reconstructed images are transmitted to the computer system 120 and stored in the memory 126. In response to commands received from the operator workstation 110, the image data may be stored in a long-term memory, or may be further processed by the image processor 128 and transmitted to the operator workstation 110 for presentation on the display 118.

In various embodiments, components of the computer system 120 and the MRI system controller 130 may be implemented on the same computer system or on a plurality of computer systems. It should be understood that the MRI system 100 shown in FIG. 10 is intended for illustration. A suitable MRI system may include more, fewer, and/or different components.

The MRI system controller 130 and the image processor 128 may separately or collectively include a computer processor and a storage medium. The storage medium records a predetermined data processing program that is to be executed by the computer processor. For example, the storage medium may store a program used to implement scan processing (for example, a scan procedure and an imaging sequence), image reconstruction, image processing, etc. For example, the storage medium may store a program used to implement the magnetic resonance scanning method according to the embodiments of the present invention. The above storage medium may include, for example, a ROM, a floppy disk, a hard disk, an optical disk, a magneto-optical disk, a CD-ROM, or a non-volatile memory card.

Description is made below in conjunction with the embodiments.

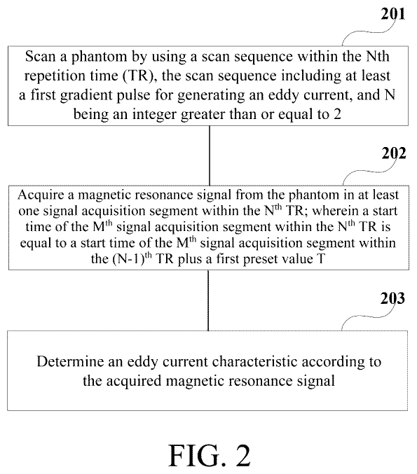

Embodiments of the present application provide an eddy current acquisition method for a magnetic resonance imaging system. FIG. 2 is a schematic diagram of an eddy current acquisition method for a magnetic resonance imaging system according to embodiments of the present application.

As shown in FIG. 2, the method includes: at 201: scanning a phantom by using a scan sequence within the N^{th} repetition time (TR), the scan sequence including at least a first gradient pulse for generating an eddy current, and N being an integer greater than or equal to 2. Step 202 of FIG. 2 includes acquiring a magnetic resonance signal from the phantom in at least one signal acquisition segment within the N^{th} repetition time (TR); wherein a start time T_{N} of the M^{th} signal acquisition segment within the N^{th} repetition time (TR) is equal to a start time T_{N-1} of the M^{th} signal acquisition segment within the (N−1)^{th} repetition time (TR) plus a first preset value T, and M is an integer greater than or equal to 1. Finally step 203 includes determining an eddy current characteristic according to the acquired magnetic resonance signal.

In some embodiments, the phantom may be placed within a scanning cavity of the magnetic resonance imaging system during system installation or calibration. The shape or size of the phantom is not limited in the embodiments of the present application.

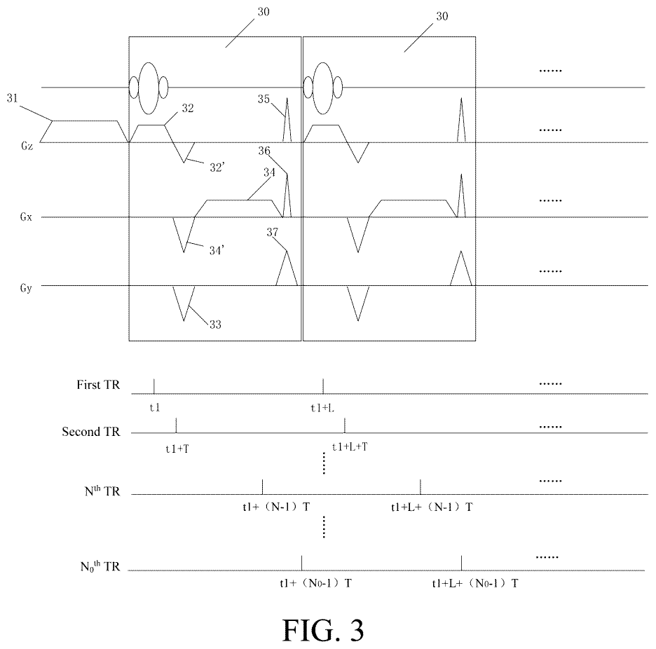

In some embodiments, FIG. 3 is a schematic diagram of a scan sequence according to embodiments of the present application. As shown in FIG. 3, the scan sequence includes a first gradient pulse for generating an eddy current and a gradient echo sequence after the first gradient pulse. The type of the gradient echo sequence is not limited in the embodiments of the present application. As shown in FIG. 3, the first gradient pulse 31 is applied in a gradient direction G_{z} for layer selection in the gradient echo sequence, and an eddy current characteristic in a direction G_{z} is correspondingly obtained. However, the embodiments of the present application are not limited thereto, and the first gradient pulse 31 may alternatively be applied in a gradient direction Gₓ for frequency encoding, and an eddy current characteristic in a direction Gₓ is correspondingly obtained, or be applied in a gradient direction G_{y} for phase encoding, and an eddy current characteristic in a direction G_{y} is correspondingly obtained. The first gradient pulse 31 is a trapezoidal wave, and a pulse width of the trapezoidal wave may be set to be longer than the time constant of the eddy current to be measured. For example, the pulse width may be set to 10 milliseconds, etc., but the embodiments of the present application are not limited thereto. The first gradient pulse 31 may be a gradient pulse in a positive direction or a gradient pulse in a negative direction.

As shown in FIG. 3, after the first gradient pulse 31 ends, a gradient echo sequence is transmitted. The gradient echo sequence includes a radio frequency pulse, a gradient pulse 32 for layer selection at a same time as the radio frequency pulse, a gradient pulse 33 for phase encoding after the gradient pulse 32, and a gradient pulse 34 for frequency encoding after the gradient pulse 33. Pulse widths and amplitudes of the pulses may be determined as required. The embodiments of the present application are not limited thereto. The gradient pulse 32 and the gradient pulse 34 may be trapezoidal waves, and the gradient pulse 33 may be a trapezoidal wave or a triangular wave. The embodiments of the present application are not limited thereto.

As shown in FIG. 3, in the direction G_{z}, after the gradient pulse 32 for layer selection, a gradient pulse 32′ in a negative direction is further applied. The gradient pulse 32′ is used to offset the eddy current generated by the gradient pulse 32, thereby preventing impact of the eddy current generated by the gradient pulse 32 on the eddy current generated by the first gradient pulse 31. The gradient pulse 32′ may be a triangular wave or a trapezoidal wave. The embodiments of the present application are not limited thereto.

As shown in FIG. 3, in the direction Gx, before the gradient pulse 34, a pre-dephasing gradient pulse 34′, in the negative direction, that is on at a same time as the gradient pulse 33 is further applied, to offset the eddy current generated by the gradient pulse 34, so as to prevent the impact of the eddy current generated by the gradient pulse 34 on the eddy current generated by the first gradient pulse 31.

As shown in FIG. 3, optionally, in the directions G_{z}, Gₓ, and G_{y}, compensating gradient pulse 35, gradient pulse 36, and gradient pulse 37 are further applied to perform sufficient dephasing, thereby preventing impact of phase accumulation generated by a previous gradient waveform on subsequent encoding. The scan sequence in FIG. 3 is only an example, and the embodiments of the present application are not limited thereto. By involving the scan sequence, the excited phantom generates a magnetic resonance signal only affected by the eddy current of the first gradient pulse.

In some embodiments, the above scan sequence is repeatedly transmitted within N₀ repetition times, and magnetic resonance signals from the phantom are acquired within the N₀ repetition times, so that eddy current characteristics at the same spatial location are obtained according to the magnetic resonance signals acquired within the N₀ repetition times, that is, a curve of the eddy current changing over time. The following first describes an operation within the N^{th} TR as an example.

In some embodiments, within the N^{th} TR, magnetic resonance signals from the phantom are acquired in P signal acquisition segments, and P is an integer greater than or equal to 1. When P is greater than 1, after the first gradient pulse is applied to the scan sequence, the gradient echo sequence 30 in FIG. 3 may be repeated P times to obtain P gradient echoes, and one signal acquisition segment is set for each gradient echo. Start times of adjacent signal acquisition segments are separated by a third preset value L, and L is a value greater than 0 and a duration of the signal acquisition segment. Values of L and P are determined as required. The values of L and P within different TRs are the same. Start times of the P signal acquisition segments within the N^{th} TR are delayed by a first preset value T as a whole relative to the P signal acquisition segments within the (N−1)^{th} TR. In other words, a start time T_{N} of the M^{th} signal acquisition segment within the N^{th} repetition time (TR) is equal to a start time T_{N-1} of the M^{th} signal acquisition segment within the (N−1)^{th} repetition time (TR) plus a first preset value T, and M is an integer greater than or equal to 1 and less than or equal to P.

In some embodiments, the first preset value T is correlated with at least one of a time constant of the eddy current, the number of signal acquisition segments, an interval between adjacent signal acquisition segments, a maximum value N₀ of N, and a repetition time. For example, if the value of N₀ is 8 and the interval between adjacent signal acquisition segments is 4000 μs, the value of T may be determined as 500 μs according to 4000/8. However, the embodiments of the present application are not limited thereto, and the value of T may alternatively be determined as 100 μs, 200 μs, 400 μs, or the like according to experience. Uniform sampling may be achieved by determining a suitable T, so that a more accurate eddy current curve is obtained.

In some embodiments, within the first TR, the start time of the first signal acquisition segment among the P signal acquisition segments is after an end of the first gradient pulse. In other words, signal acquisition can only be started after an end of the first gradient pulse, for example, the start time of the first signal acquisition segment within the first TR is at a central location of the first radio frequency pulse of the scan sequence or the start time of the first gradient pulse 34. Considering limitation of an echo time (TE), a time t1 at which the signal is actually acquired in the first signal acquisition segment within the first TR may be the central location of the first radio frequency pulse plus TE. In other words, as shown in FIG. 3, within the first TR, the start times of the P signal acquisition segments are t1, t1+L, t1+2L, . . . , t1+(P−1)L, respectively. Within the second TR, the start times of the P signal acquisition segments are t1+T, t1+L+T, t1+2L+T, . . . , t1+(P−1)L+T, and so on. Within the N^{th} TR, the start times of the P signal acquisition segments are t1+(N−1)T, t1+L+(N−1)T, t1+2L+(N−1)T, . . . , t1+(P−1)L+(N−1)T, and so on. Within the N₀^{th} TR, the start times of the P signal acquisition segments are t1+(N₀−1)T, t1+L+(N₀−1)T, t1+2L+(N₀−1)T, . . . , t1+(P−1)L+(N₀−1)T, respectively.

In some embodiments, when P is greater than 1, steps 201 and 202 are repeatedly executed, until the start time of the first signal acquisition segment within the N^{th} repetition time (TR) is greater than or equal to the start time of the second signal acquisition segment within the first repetition time (TR). In other words, the start time of the first signal acquisition segment within the N₀^{th} repetition time (TR) is greater than or equal to the start time of the second signal acquisition segment within the first repetition time (TR), but the start time of the first signal acquisition segment within the (N₀−1)^{th} repetition time (TR) does not exceed the start time of the second signal acquisition segment within the first repetition time (TR). Therefore, P×N₀ magnetic resonance signals acquired within N₀ repetition times are obtained. For example, start times of two signal acquisition segments within the first TR are 1000 μs and 4500 μs, respectively. When T=500 us, the start time of the first signal acquisition segment with the seventh TR is 4000 μs, and the start time of the first signal acquisition segment within the eighth TR is 4500 μs. Therefore, when N₀ is equal to 7, or when N=8, 201 and 202 are no longer repeatedly executed.

In some embodiments, steps 201 and 202 are repeatedly executed, until the number of N is greater than a second preset value. In other words, N₀ is a second preset value, which may be determined as required. For example, when P=1, N₀ magnetic resonance signals acquired within N₀ repetition times are obtained, and the value of the second preset value N₀ needs to be sufficient for fitting, to obtain an eddy current curve.

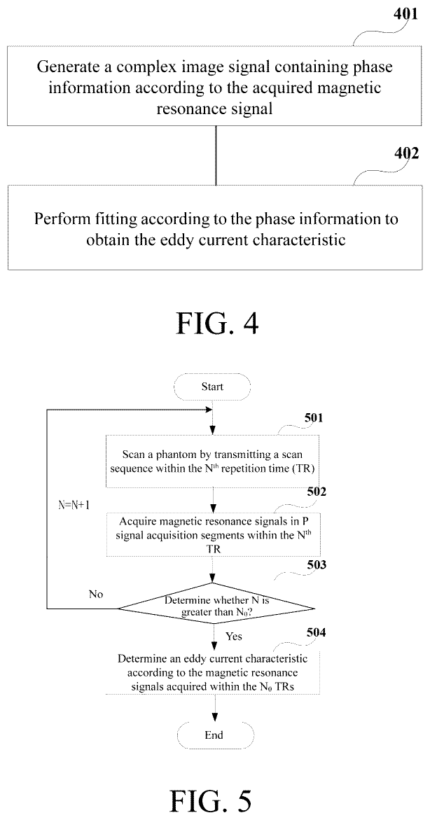

In some embodiments, after the P×N₀ magnetic resonance signals are acquired within the N₀ repetition times, in 203, an eddy current characteristic is determined according to the P×N₀ magnetic resonance signals. FIG. 4 is a schematic diagram of an implementation of step 203 according to embodiments of the present application.

As shown in FIG. 4, step 203 includes at step 401: generating a complex image signal containing phase information according to the acquired magnetic resonance signal; and at step 402: performing fitting according to the phase information to obtain the eddy current characteristic.

In some embodiments, a Fourier transform is performed according to the acquired magnetic resonance signal to obtain a complex image signal. Phase information of the complex image signal is an eddy current value at a corresponding time point. By performing non-linear fitting or polynomial fitting of an E-index decay model on the P×N₀ eddy current values, a fitting curve is obtained. The foregoing are only examples for description. Embodiments of the present application are not limited thereto. The fitting curve may represent a variation law of an eddy current over time. Therefore, an eddy current time constant may also be obtained.

As can be seen from the above embodiments, by means of cyclic delayed acquisition, time locations of signal acquisition within different TRs are changed, so that a sufficient number of sampling points are obtained within a short time after the eddy current is generated to fit an eddy current curve, thereby accurately acquiring high-order eddy current changes having short time constants.

In addition, it is not necessary to set a plurality of signal acquisition segments within one repetition time, and by means of delayed acquisition for a plurality of times, a sufficient number of sampling points may be obtained within a short time after generation of the eddy current by using one or two signal acquisition segments, to fit an eddy current curve, so as to further reduce scanning time.

FIG. 5 is a schematic diagram of an eddy current acquisition method according to embodiments of the present application. As shown in FIG. 5, for a curve of an eddy current changing over time at the same spatial location (for example, the same phase encoding line at the same slice location), the method includes steps 501 to 504.

At step 501 the method includes scanning a phantom by transmitting a scan sequence within the N^{th} repetition time (TR); an initial value of N being 1; and at step 502 the method includes acquiring magnetic resonance signals in P signal acquisition segments within the N^{th} TR. At step 503, it is determined whether N is greater than N₀; if so, the method proceeds to step 504, and if not, N is incremented by one (N=N+1) and the process returns to step 501. At step 504, an eddy-current characteristic is determined based on the magnetic resonance signals acquired within the N₀ TRs.

A signal acquisition process within N₀ repetition times is described below with reference to an example. Assuming that P=2, t1=1000 μs, L=3000 μs, T=500 μs,
start times of signal acquisition within the first TR are: 1000 μs and 4500 μs;
start times of signal acquisition within the second TR are: 1500 μs and 5000 μs;
start times of signal acquisition within the third TR are: 2000 μs and 5500 μs;
start times of signal acquisition within the fourth TR are: 2500 μs and 6000 μs;
start times of signal acquisition within the fifth TR are: 3000 μs and 6500 μs;
start times of signal acquisition within the sixth TR are: 3500 μs and 7000 μs; and
start times of signal acquisition within the seventh TR are: 4000 μs and 7500 μs.

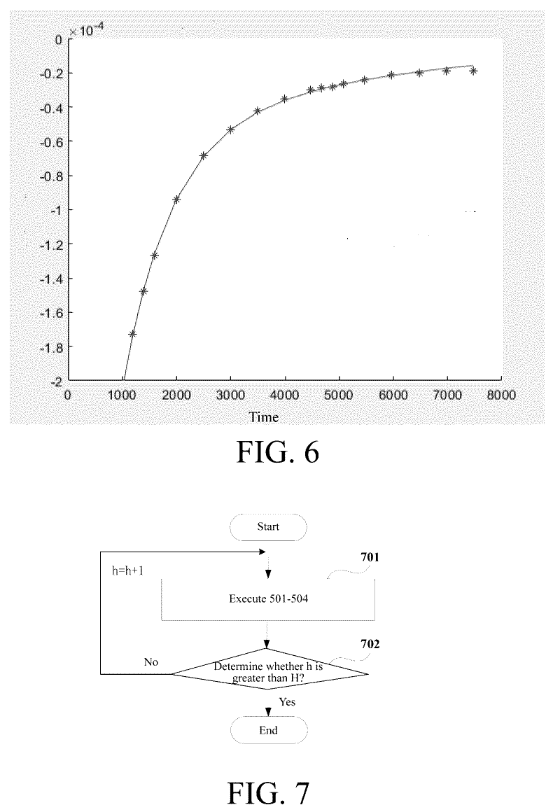

If 4000 μs is delayed by 500 μs, the start time is equal to the start time of the second signal acquisition segment within the first TR. Therefore, delayed acquisition is stopped, and the eddy current curve is obtained according to the signals acquired within the seven TRs. FIG. 6 is an eddy current curve obtained by fitting according to the foregoing signal acquisition process according to embodiments of the present application.

In some embodiments, in order to eliminate the impact caused by a non-eddy current, positive and negative polarities of the first gradient pulse in the scan sequence may further be switched (if the pulse polarity of the original first gradient pulse is positive, the pulse polarity is switched to negative, and if the pulse polarity of the original first gradient pulse is negative, the pulse polarity is switched to positive), and the operations in FIG. 5 are repeatedly executed, so as to obtain a curve of the eddy current corresponding to different gradient polarities changing over time at the same spatial location.

In some embodiments, in order to obtain spatial distribution of the eddy current curve, the operations in FIG. 5 may be separately executed for different phase encoding lines at the same slice location, so as to obtain eddy current curves corresponding to different phase encoding line locations. The difference lies in that the phase encoding gradients in the scan sequence corresponding to different phase encoding lines are different. In other words, a matrix size of one slice location in the phase encoding direction is referred to as the number of phase encoding lines, and the matrix size may be 32, 64, 128, 256, or other values. In order to obtain space-time distribution of an eddy current at the same slice location, a total scanning time may be TR×the number of phase encoding lines×N₀×the number of gradient polarities (2).

FIG. 7 is a schematic diagram of an eddy current acquisition method according to embodiments of the present application. As shown in FIG. 7, for a curve of an eddy current changing over time at the same slice position, assuming that an image resolution is H×H, the method includes: at step 701 executing 501 to 504; and at step 702: resetting the value of N to 1; and determining whether h is greater than H, and ending the process when h is greater than H, or otherwise h=h+1, and returning to 701, an initial value of h being 1.

In other words, 701 is separately executed for different h, but phase encoding gradients in scan sequences corresponding to different h are different. That is, the phase encoding gradient is different in each cycle.

In some embodiments, in order to obtain spatial distribution of the eddy current curve, the operations in FIG. 5 may also be separately executed for different slice locations, so as to obtain eddy current curves corresponding to the spatial locations of different slices. The difference lies in that the radio frequency pulse frequencies in the scan sequences corresponding to different slice locations are different. In other words, in order to obtain space-time distribution of an eddy current at different slice locations, a total scanning time may be the number of slice locations×TR×the number of phase encoding lines×N₀×the number of gradient polarities (2).

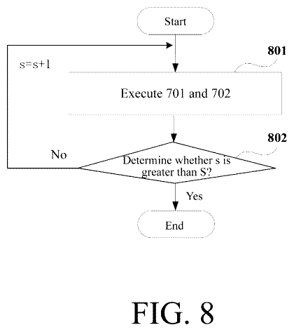

FIG. 8 is a schematic diagram of an eddy current acquisition method according to embodiments of the present application. For eddy current curves changing over time at different slice locations, assuming that there are S slice locations, as shown in FIG. 8, the method includes at step 801: executing 701 and 702; and at step 802: resetting the value of h to 1, determining whether s is greater than S, ending the process when s is greater than S, or otherwise s=s+1, returning to 801, an initial value of s being 1.

In other words, 801 is separately executed for different s, but the radio frequency pulse frequencies in the scan sequences corresponding to different s are different. That is, the radio frequency pulse frequency in each cycle is different.

In some embodiments, after the space-time distribution curve of the eddy current is obtained, compensation may be performed according to the eddy current characteristic during a formal scan.

For example, a phase change at each time may be calculated according to the eddy current curve, and the phase is compensated in real time by using the eddy current curve during a signal acquisition process of a formal scan. In an image reconstruction process, a fitted change value may be deducted from an actually acquired signal phase, so as to eliminate a phase error caused by the eddy current.

For example, the gradient waveform in the formal scan sequence is adjusted according to the eddy current characteristic. For example, a rapid switch is prevented in a smooth gradient waveform, or gradient pre-adjustment is used, to reduce the impact of the eddy current by applying a certain reverse gradient. For phase encoding in each direction, the polarities of the positive and negative gradients may be adjusted according to the eddy current curve. For example, application times of the forward and reverse gradients are adjusted according to the eddy current time constant, so that the impact of the eddy current is minimized.

For example, during signal acquisition, a reverse gradient (reverse phase) may be applied according to the eddy current characteristic, to correct the phase mismatch caused by the eddy current. A reverse operation may enable signal phases to restore consistency, so as to compensate for the impact of the eddy current.

The foregoing are only examples. Embodiments of the present application are not limited thereto.

It should be noted that the above figures merely schematically illustrate the embodiments of the present application, but the present application is not limited thereto. For example, the order of execution between operations may be appropriately adjusted. In addition, some other operations may be added or some operations may be omitted. Those skilled in the art can make appropriate variations according to the above content, rather than being limited by the disclosure of the foregoing accompanying drawings.

The above embodiments merely provide illustrative descriptions of the embodiments of the present application. However, the present application is not limited thereto, and suitable variations may be made on the basis of the above embodiments. For example, each of the above embodiments may be used independently, or one or more of the above embodiments may be combined.

According to the above embodiments, by means of cyclic delayed acquisition, time locations of signal acquisition within different TRs are changed, so that a sufficient number of sampling points are obtained within a short time after the eddy current is generated to fit an eddy current curve, thereby accurately acquiring high-order eddy current changes having short time constants.

Embodiments of the present application further provide a magnetic resonance imaging system. The configuration of the magnetic resonance imaging system is as shown in FIG. 1, and what are the same will not be repeated here.

In some embodiments, what differs from the foregoing magnetic resonance imaging system in FIG. 1 is that the controller 130 is configured to execute the foregoing eddy current acquisition method.

In some embodiments, the controller 130 (which may also be a processor) includes a computer processor and a storage medium. The storage medium has recorded thereon a predetermined data processing program to be executed by the computer processor. For example, the storage medium may store a program configured to implement scan processing (for example, including waveform design/conversion, and the like), image reconstruction, image processing, etc. For example, the storage medium may store an eddy current acquisition method according to embodiments of the present application. The specific implementation thereof is as described above, and will not be described herein again.

The above storage medium may include, for example, a ROM, a floppy disk, a hard disk, an optical disk, a magneto-optical disk, a CD-ROM, or a non-volatile memory card.

The embodiments of the present application further provide a computer-readable program. When the program is executed in an apparatus or an MRI system, the program enables a computer to execute, in the apparatus or the MRI system, the method according to the foregoing embodiments.

Embodiments of the present application further provide a storage medium having a computer-readable program stored thereon. The computer-readable program causes a computer to execute the method according to the foregoing embodiments in an apparatus or MRI system.

The above apparatus and method of the present application can be implemented by hardware, or can be implemented by hardware in combination with software. The present application relates to such a computer-readable program that when executed by a logic component, the program causes the logic component to implement the foregoing apparatus or a constituent component, or causes the logic component to implement various methods or steps as described above. The present application further relates to a storage medium for storing the above program, such as a hard disk, a magnetic disk, an optical disc, a DVD, a flash memory, etc.

The method/apparatus described with reference to the embodiments of the present application may be directly embodied as hardware, a software module executed by a processor, or a combination of the two. For example, one or more of the functional block diagrams and/or one or more combinations of the functional block diagrams shown in the figures may correspond to either software modules or hardware modules of a computer program flow. The foregoing software modules may respectively correspond to the steps shown in the figures. The foregoing hardware modules may be implemented, for example, by consolidating the foregoing software modules by using a field-programmable gate array (FPGA).

The software modules may be located in a RAM memory, a flash memory, a ROM memory, an EPROM memory, an EEPROM memory, a register, a hard disk, a removable disk, a CD-ROM, or any storage medium in other forms known in the art. The storage medium may be coupled to a processor, so that the processor can read information from the storage medium and can write information into the storage medium. Alternatively, the storage medium may be a constituent component of the processor. The processor and the storage medium may be located in an ASIC. The software module may be stored in a memory of a mobile terminal, and may also be stored in a memory card that can be inserted into a mobile terminal. For example, if a device (such as a mobile terminal) uses a large-capacity MEGA-SIM card or a large-capacity flash memory apparatus, then the software modules may be stored in the MEGA-SIM card or the large-capacity flash memory apparatus.

One or more of the functional blocks and/or one or more combinations of the functional blocks shown in the drawings may be implemented as a general-purpose processor, a digital signal processor (DSP), an application-specific integrated circuit (ASIC), a field-programmable gate array (FPGA) or other programmable logic devices, a discrete gate or transistor logic device, a discrete hardware assembly, or any appropriate combination thereof, which is used for executing the functions described in the present application. The one or more functional blocks and/or the one or more combinations of the functional blocks shown in the drawings may alternatively be implemented as a combination of computing devices, such as a combination of a DSP and a microprocessor, a plurality of microprocessors, one or more microprocessors in communication combination with a DSP, or any other such configuration.

The present application is described above with reference to specific implementations. However, it should be clear to those skilled in the art that the foregoing description is merely illustrative and is not intended to limit the scope of protection of the present application. Various variations and modifications may be made by those skilled in the art according to the principle of the present application, and said variations and modifications also fall within the scope of the present application.

1. An eddy current acquisition method for a magnetic resonance imaging system, characterized by comprising:
scanning a phantom by using a scan sequence within the N^{th} repetition time, the scan sequence comprising at least a first gradient pulse for generating an eddy current, and N being an integer greater than or equal to 2;
acquiring a magnetic resonance signal from the phantom in at least one signal acquisition segment within the N^{th} repetition time; wherein a start time T_{N} of the M^{th} signal acquisition segment within the N^{th} repetition time is equal to a start time T_{N-1} of the M^{th} signal acquisition segment within the (N−1)^{th} repetition time plus a first preset value T, and M is an integer greater than or equal to 1; and
determining an eddy current characteristic according to the acquired magnetic resonance signal.

2. The method according to claim 1, wherein the scan sequence further comprises a gradient echo sequence after the first gradient pulse.

3. The method according to claim 2, wherein the first gradient pulse is applied in a gradient direction for layer selection in the gradient echo sequence, or applied in a gradient direction for frequency encoding, or applied in a gradient direction for phase encoding.

4. The method according to claim 1, wherein a start time of the first signal acquisition segment within the first repetition time is after an end of the first gradient pulse.

5. The method according to claim 1, wherein a start time of the first signal acquisition segment within the first repetition time is located at a central location of the first radio frequency pulse of the scan sequence.

6. The method according to claim 1, wherein the number of signal acquisition segments within one repetition time is 1 or 2.

7. The method according to claim 1, wherein the first preset value is correlated with at least one of a time constant of the eddy current, the number of signal acquisition segments, an interval between adjacent signal acquisition segments, a maximum value of N, and a repetition time.

8. The method according to claim 1, wherein the phantom is scanned by using the scan sequence and magnetic resonance signals are acquired from the phantom within the N^{th} repetition time, until a start time of the first signal acquisition segment within the N^{th} repetition time is greater than or equal to a start time of the second signal acquisition segment within the first repetition time, or until the number of N is greater than a second preset value.

9. The method according to claim 1, wherein determining an eddy current characteristic according to the acquired magnetic resonance signal comprises:
generating a complex image signal containing phase information according to the acquired magnetic resonance signal; and
performing fitting according to the phase information to obtain the eddy current characteristic.

10. A magnetic resonance imaging system, characterized by comprising:
a scanning unit; and
a controller, which is configured to execute the eddy current acquisition method according to claim 1.
